(19) United States
(12) Patent Application Publication
(10) Pub. No.: US 2024/0339568 A1
(43) Pub. Date: Oct. 10, 2024

(54) RARE-EARTH-DOPED SEMICONDUCTOR DEVICE AND METHOD FOR PRODUCING THE SAME

(71) Applicant: OSAKA UNIVERSITY, Suita-shi, Osaka (JP)

(72) Inventors: Yasufumi FUJIWARA, Suita-shi (JP); Tsuyoshi UEMURA, Suita-shi (JP); Kazutsune MIYANAGA, Suita-shi (JP); Norio KANZAKI, Suita-shi (JP)

(73) Assignee: OSAKA UNIVERSITY, Suita-shi, Osaka (JP)

(21) Appl. No.: 18/580,106

(22) PCT Filed: Jul. 15, 2022
(86) PCT No.: PCT/JP2022/027819

§ 371 Date: Jan. 17, 2024

(30) Foreign Application Priority Data
Jul. 21, 2021 (JP) 2021-120455

(51) Int. Cl. H01L 33/32; H01L 33/00; H01S 5/30; H01S 5/323

(52) U.S. Cl. CPC H01L 33/325; H01L 33/0075; H01S 5/3063; H01S 5/3086; H01S 5/323

(57) ABSTRACT

The present invention provides: a rare-earth-doped semiconductor device which has further improved EQE %, while having excellent emission intensity; and a method for producing the rare-earth-doped semiconductor device. A rare-earth-doped semiconductor device in which an active layer that is obtained by adding a rare earth element to a base material that is composed of GaN, InN, AlN or an alloy compound semiconductor of any two or more of these compounds is arranged between an n-type layer and a p-type layer, wherein a p-type doped layer in which a p-type dopant is added together with a rare earth element is formed in the p-type layer side of the active layer. A method for producing a rare-earth-doped semiconductor device, wherein: formation of an n-type layer, formation of an active layer and formation of a p-type layer are performed by a series of formation steps under the temperature conditions of 900° C. to 1200° C. with use of an organic metal vapor deposition method without being taken out of a reaction vessel; and when the active layer is formed, a p-type doped layer is formed in the p-type layer side of the active layer by adding a p-type dopant together with a rare earth element.

### TECHNICAL FIELD

The present invention relates to a rare-earth-doped semiconductor device with excellent emission intensity and a method for producing the same.

### BACKGROUND OF THE INVENTION

In recent years, light emitting devices such as light emitting diodes (LED: Light Emitting Diode) and laser diodes (LD: Laser Diode) have come to be widely used. For example, LEDs are used for various display devices, backlights for liquid crystal displays including for mobile phones, white lighting, etc., while LDs are used for recording and playback of high-definition video as light sources for Blue-ray discs, optical communication, CDs, DVDs, etc.

Recently, applications are expanding for high-frequency devices such as MMICs (monolithic microwave integrated circuits) for mobile phones, and HEMTs (high electron mobility transistors), and for high power devices such as power transistors for inverters for automobiles, and schottky barrier diodes (SBDs).

Under these circumstances, the inventors of the present invention have developed, ahead of the world, a red light-emitting semiconductor device with high emission intensity, which has GaN doped with europium (Eu), which is one of the rare earth elements, as an active layer (light emitting layer). (For example, Patent documents 1 and 2).

A semiconductor device having an active layer doped with rare earth elements such as Eu (rare-earth-doped semiconductor device) has an active layer formed between two transport layers (an n-type layer and a p-type layer) that transport electrons and holes respectively, which are carriers. After each carrier (electron, hole) injected from the positive and negative electrodes, respectively, moves within the active layer via the respective transport layer (n-type layer, p-type layer), then they recombine within the active layer, and the energy generated at that time is transferred to the rare earth element, which emits light.

The light emission mechanism in this rare-earth-doped semiconductor device is completely different from the light emission mechanism in conventional general semiconductor devices, which emits light by interband transition in the active layer, and emits light by 4f shell intra-center transition of the rare earth element (ion). For this reason, this rare-earth-doped semiconductor device exhibits excellent characteristics that were unimaginable in the light emitted by conventional semiconductor devices, such as an extremely sharp emission spectrum and the fact that the emission wavelength does not change depending on the environmental temperature.

The present inventors have found that the emission intensity can be further improved by selectively arranging magnesium (Mg) around Eu when forming the active layer of the rare-earth-doped semiconductor device described above to control the local structure around Eu ions, specifically greatly reduce the symmetry of Eu ions (Patent document 3).

### PRIOR ART DOCUMENTS

### Patent document

[Patent document 1] JP 5388041 B
[Patent document 1] JP 5896454 B
[Patent document 1] JP 6450061 B

### SUMMARY OF THE INVENTION

### Problems to be Solved by the Invention

However, in recent years, the needs of society for improving emission intensity have become stronger and stronger, and the above-mentioned technologies have not yet been able to sufficiently meet the needs; and there is a need for rare-earth-doped semiconductor devices with further improved emission intensity.

Therefore, the present inventor measured how much light can be extracted from the active layer to the outside, that is, external quantum efficiency (EQE %), the efficiency, in a conventional rare-earth-doped semiconductor device. Specifically, EQE % was determined by measuring the number of photons emitted by the rare-earth-doped semiconductor device being excited.

As a result, the EQE % of conventional rare-earth-doped semiconductor devices remained at around 0.30%, and it was found that by improving this EQE %, it was possible to provide rare-earth-doped semiconductor devices with even better emission intensity.

Therefore, an object of the present invention is to provide a rare-earth-doped semiconductor device that further improves EQE % and has excellent emission intensity, and a method for producing the same.

### Means for Solving the Problems

The inventors of the present invention have conducted intensive studies to solve the above-mentioned problems, and have found that the above-mentioned problems can be solved by the invention described below, and have completed the present invention.

The inventions according to claim 1 is
a rare-earth-doped semiconductor device using GaN, InN, AlN, or an alloy compound semiconductor of two or more of these as a base material and
a rare earth-doped active layer is provided between an n-type layer and a p-type layer,
characterized in that a p-type doped layer in which a p-type dopant is added together with a rare earth element is formed in the p-type layer side of the active layer.

The inventions according to claim 2 is
the rare-earth-doped semiconductor device according to claim 1, characterized in that the concentration of the p-type dopant decreases from the p-type layer side toward an inner layer portion, in the p-type doped layer.

The inventions according to claim 3 is
the rare-earth-doped semiconductor device according to claim 1 or 2, characterized in that the p-type doped layer is formed by stacking a plurality of layers having different concentrations of the p-type dopant so that the concentration of the p-type dopant decreases from the p-type layer side toward the inner layer portion.

The inventions according to claim 4 is
the rare-earth-doped semiconductor device according to any one of claims 1 to 3, characterized in that the p-type doped layer is formed to have a thickness of ¼ to ½ of the active layer.

The inventions according to claim 5 is
the rare-earth-doped semiconductor device according to any one of claims 1 to 4, characterized in that the concentration of the rare earth element in the active layer is 1×10¹⁷ to 5×10²¹ cm⁻³.

The inventions according to claim 6 is
the rare-earth-doped semiconductor device according to any one of claims 1 to 5, characterized in that the rare earth element is europium (Eu).

The inventions according to claim 7 is
the rare-earth-doped semiconductor device according to any one of claims 1 to 6, characterized in that the concentration of the p-type dopant in the vicinity of the interface between the active layer and the p-type layer is 1×10¹⁷ to 1×10²⁰ cm⁻³.

The inventions according to claim 8 is
the rare-earth-doped semiconductor device according to any one of claims 1 to 7, characterized in that the p-type dopant is magnesium (Mg).

The inventions according to claim 9 is
the rare-earth-doped semiconductor device according to any one of claims 1 to 8, characterized in that oxygen element is further added to the active layer.

The inventions according to claim 10 is
the rare-earth-doped semiconductor device according to claim 9, characterized in that the concentration of the oxygen element in the active layer is 1×10¹⁷ to 1×10²⁰ cm⁻³.

The inventions according to claim 11 is
a method for producing a rare-earth-doped semiconductor device having an active layer formed by using GaN, InN, AlN, or an alloy compound semiconductor of two or more of these as a base material and adding a rare earth element which is formed between an n-type layer and a p-type layer, characterized in that
the formation of the n-type layer, the formation of the active layer, and formation of the p-type layer are performed in a series under the temperature conditions of 900 to 1200° C. using organometallic vapor phase epitaxy without being taken out from the reaction vessel; and, when forming the active layer, a p-type dopant is added together with a rare earth element to the p-type layer side of the active layer to form a p-type doped layer.

The inventions according to claim 12 is
the method for producing a rare-earth-doped semiconductor device according to claim 11, characterized in that the atmospheric pressure when forming the active layer is 5 to 60 kPa.

The inventions according to claim 13 is
the method for producing a rare-earth-doped semiconductor device according to claim 11 or claim 12, characterized in that the growth rate when forming the active layer is 0.1 to 4μ m/h.

The inventions according to claim 14 is
the method for producing a rare-earth-doped semiconductor device according to any one of claims 11 to 13, characterized in that after forming the n-type layer on a substrate, an active layer of a predetermined thickness is formed by adding a rare earth element to the base material, then a p-type doped layer of a predetermined thickness is formed by adding a p-type dopant together with a rare earth element to the base material, followed by forming the p-type layer.

The inventions according to claim 15 is
the method for producing a rare-earth-doped semiconductor device according to any one of claims 11 to 14, characterized in that after forming the p-type layer on a substrate,
a p-type doped layer of a predetermined thickness is formed by adding a p-type dopant together with a rare earth element to the base material, then
an active layer of a predetermined thickness is formed by adding a rare earth element to the base material, followed by forming the n-type layer.

The inventions according to claim 16 is
the method for producing a rare-earth-doped semiconductor device according to any one of claims 11 to 15, characterized in that europium (Eu) is used as the rare earth element and magnesium (Mg) is used as the p-type dopant.

### Effect of the Invention

According to the present invention, it is possible to further improve EQE % and provide a rare-earth-doped semiconductor device having excellent emission intensity and a method for manufacturing the same.

### BRIEF DESCRIPTION OF THE DRAWINGS

FIG. 1 A schematic diagram showing the configuration of a rare-earth-doped semiconductor device according to the present invention.

FIG. 2 A diagram illustrating recombination of carriers in the rare-earth-doped semiconductor device according to the present invention.

FIG. 3 A diagram illustrating changes in the concentration of p-type dopants in the active layer.

FIG. 4 A diagram illustrating the extent of a recombination region in an active layer.

FIG. 5 A diagram showing an example of secondary ion mass spectrometry results of rare-earth-doped semiconductor devices obtained in Examples.

FIG. 6 A diagram illustrating the relationship between the driving voltage and the p-type doped layer in an example.

FIG. 7 A diagram illustrating the relationship between optical output and a p-type doped layer in an example.

FIG. 8 A diagram illustrating the relationship between EQE % and a p-type doped layer in an example.

FIG. 9 A schematic diagram showing the configuration of a conventional rare-earth-doped semiconductor device.

FIG. 10 A diagram illustrating recombination of carriers in a conventional rare-earth-doped semiconductor device.

### EMBODIMENTS FOR CARRYING OUT THE INVENTION

### 1. Background to the Completion of the Present Invention

The background to the completion of the present invention will be explained below.

The present inventors have conducted various experiments and studies in order to find out the reason why EQE % remains at a low level of about 0.30% in conventional rare-earth-doped semiconductor devices.

As a result, it was found that, in the rare-earth-doped semiconductor device, as described above, the respective carriers (electrons, holes) injected from the positive and negative electrodes move through the respective transport layers (n-type layer, p-type layer) and recombine within the active layer (light emitting layer) to emit light, but in the case of conventional rare-earth-doped semiconductor devices, the injection and movement of holes within the active layer is slow, resulting in a low EQE %.

In other words, it was found that, if the injection and movement of holes are slower than the injection and movement of electrons, the carrier balance between electrons and holes deteriorates in the active layer, so the probability of recombination of electrons and holes (recombination probability) decreases, causing a decrease in EQE %, and that sufficient emission intensity was not obtained.

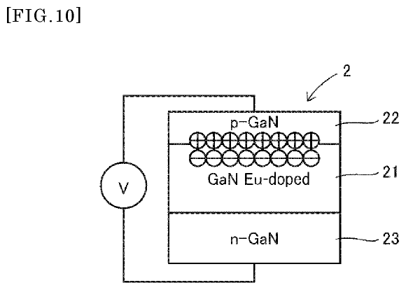

This will be specifically explained using FIGS. 9 and 10. FIG. 9 is a schematic diagram showing the configuration of a conventional rare-earth-doped semiconductor device. FIG. 10 is a diagram illustrating recombination of carriers in a conventional rare-earth-doped semiconductor device. In FIGS. 9 and 10, 2 is a rare-earth-doped semiconductor device, 21 is an active layer, 22 is a p-type layer, and 23 is an n-type layer. Note that in FIGS. 9 and 10, GaN is used as the base material, and Eu is used as the rare earth element.

As shown in FIG. 9, in the conventional rare-earth-doped semiconductor device 2, the active layer 21 is formed only of a layer in which a rare earth element (Eu) is added to a base material (GaN). In the case of such an active layer 21, since carriers (holes) injected from the positive electrode cannot move at a sufficient moving speed within the active layer 21, the carrier balance deteriorates between it and carriers (electrons) that are injected from the negative electrode and move at a sufficient moving speed within the active layer 21.

As a result, it was found that, as shown in FIG. 10, carriers (holes) injected from the positive electrode and carriers (electrons) injected from the negative electrode recombine not at the center of the active layer 21 but in the p-type layer 22 side of the active layer 21; and, as a result, the probability of carriers recombining with each other (recombination probability) is not sufficiently secured and decreases, so EQE % remains at a low level and high emission intensity cannot be achieved.

Therefore, the present inventors thought that if the deterioration of the carrier balance between electrons and holes described above can be resolved, the recombination probability will increase, EQE % will improve, and high emission intensity can be obtained, and conducted further experiments and studies

As a result, the present inventors came up with the idea of providing a p-type doped layer in which a p-type dopant is added together with a rare-earth element in the active layer doped with a rare-earth element. That is, when a p-type doped layer is provided, holes can move at a sufficient moving speed within the p-type doped layer, so the movement of holes within the active layer is promoted, and it was thought that the deterioration of the carrier balance between electrons and holes could be resolved and the recombination probability would be improved.

However, if the entire active layer is made of a p-type doped layer, although the movement of holes can be promoted, the movement of electrons is suppressed by the p-type dopant on the n-type layer side, and it was found that the recombination probability decreased. Further experiments and studies revealed that if a p-type doped layer is provided in the p-type layer side of the active layer, preferably on a thickness of ¼ to ½ from the p-type layer side of the active layer, the carrier balance between electrons and holes becomes appropriate and the recombination probability improves. Thus, the present invention was completed.

### 2. Rare-Earth-Doped Semiconductor Device According to the Present Invention

Hereinafter, the rare-earth-doped semiconductor device according to the present invention will be explained.

The rare-earth-doped semiconductor device according to the present invention uses GaN, InN, AlN, or an alloy compound semiconductor of two or more of these as a base material, and an active layer formed by adding a rare earth element is provided between an n-type layer and a p-type layer; and is characterized in that a p-type doped layer in which a p-type dopant is added together with a rare earth element is formed in the p-type layer side of the active layer.

In this way, by forming the p-type doped layer in the p-type layer side of the active layer, as mentioned above, the carrier balance between electrons and holes becomes appropriate, which improves the recombination probability, and EQE % and emission intensity can be improved.

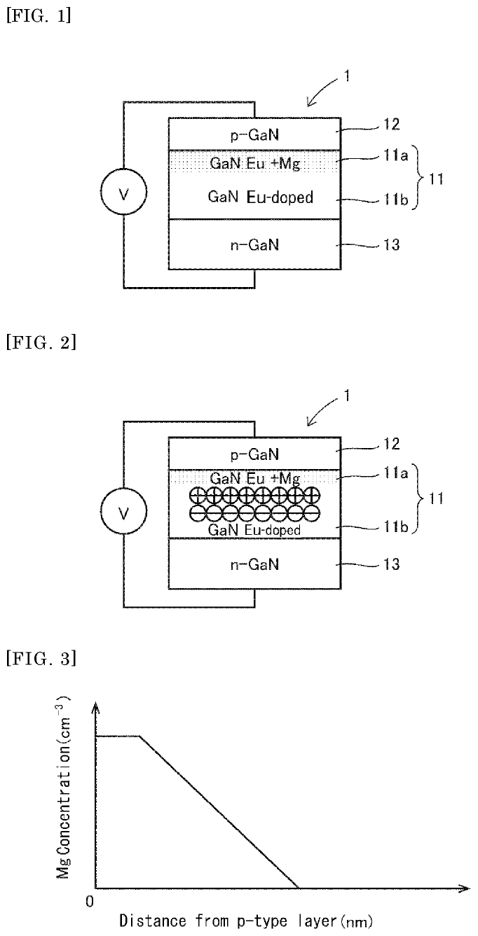

This will be specifically explained using FIGS. 1 and 2. FIG. 1 is a schematic diagram showing the configuration of a rare-earth-doped semiconductor device according to the present invention. FIG. 2 is a diagram illustrating recombination of carriers in the rare-earth-doped semiconductor device according to the present invention. In FIGS. 1 and 2, 1 is a rare-earth-doped semiconductor device, 11 is an active layer, 12 is a p-type layer, and 13 is an n-type layer. Note that in FIGS. 1 and 2, GaN is used as the base material and Eu is used as the rare earth element.

As shown in FIGS. 1 and 2, in the rare-earth-doped semiconductor device 1 according to the present invention, unlike the conventional rare-earth-doped semiconductor device 2 shown in FIGS. 9 and 10, the active layer 11 is formed of two layers: a p-type doped layer 11a in which a rare earth element (Eu) and a p-type dopant (Mg) are added to base material (GaN), and an Eu-doped active layer 11b in which only Eu is added to GaN.

Therefore, in the case of the rare-earth-doped semiconductor device 1 according to the present invention, carriers (holes) injected from the positive electrode can move within the p-type doped layer 11a without any problem. On the other hand, carriers (electrons) injected from the negative electrode can also move without any problem in the Eu-doped active layer 11b to which no p-type dopant is added. Therefore, carrier balance can be improved.

As a result, as shown in FIG. 2, carriers (holes) injected from the positive electrode are recombined with carriers (electrons) injected from the negative electrode at the center of the active layer 11. Therefore, it is possible to sufficiently secure the probability that carriers recombine with each other (recombination probability), and improve the EQE % and the emission intensity.

At this time, the p-type doped layer 11a may be a single layer formed with a predetermined p-type dopant concentration, but from the viewpoint of promoting hole injection and movement, as shown in FIG. 3, it is preferable that the concentration of the p-type dopant decreases from the p-type layer side of the active layer toward the inner layer portion. Note that FIG. 3 is a diagram illustrating changes in the concentration of p-type dopant (Mg) in the active layer, where the vertical axis represents the Mg concentration and the horizontal axis represents the distance from the p-type layer. In FIG. 3, the Mg concentration is reduced linearly within a single active layer, but it is also possible to adopt an embodiment in which a plurality of p-type doped layers are stacked and the Mg concentration is lowered stepwise.

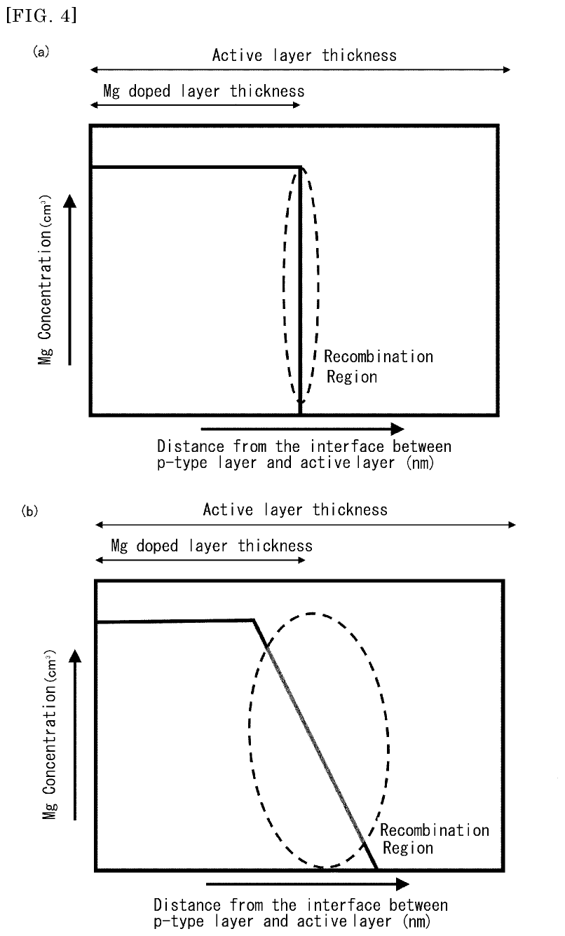

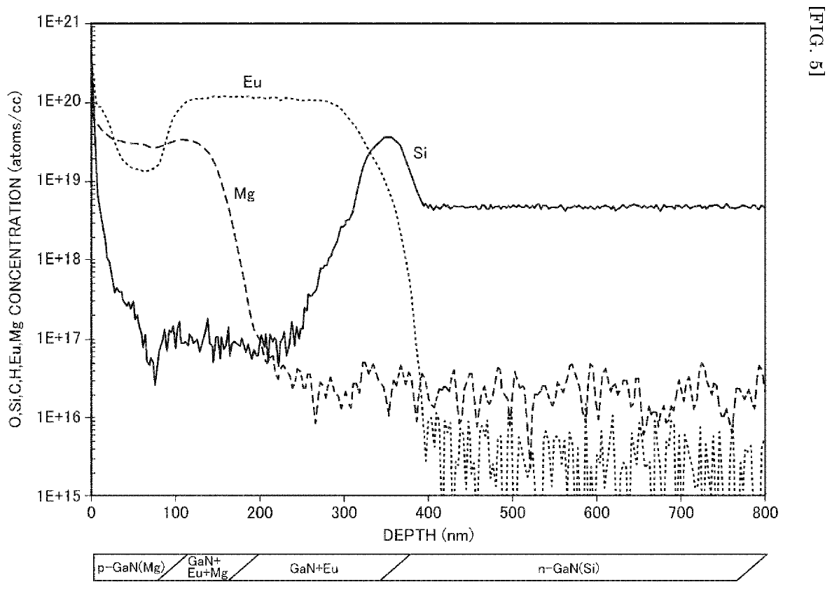

By changing the Mg concentration in the thickness direction of the active layer in this way, it is possible to widen the recombination region between carriers (holes, electrons) in the active layer. FIG. 4 is a diagram explaining the width of the recombination region in this active layer, where (a) shows a case where the Mg concentration is sharply decreased, and (b) shows a case where the Mg concentration is changed in the thickness direction of the active layer, in which the region indicated by the dashed ellipse is the recombination region. From FIG. 4, it can be seen that when the Mg concentration is sharply decreased (a), the recombination region is narrow, whereas when the Mg concentration is changed in the thickness direction of the active layer (b), the recombination region is expanded, and an improvement in EQE % can be expected.

In the present invention, specific examples of rare earth elements include scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

Among the rare earth elements mentioned above, Eu is preferred. When an organic Eu compound such as EuCp^{pm}₂ (bis(n-propyltetramethyl cyclopentadienyl) europium) and Eu (DPM)₃ (tris(2,2,6,6-tetramethyl-3,5-heptanedionato) europium) is used, it can be efficiently added to the base material, because the vapor pressure within the reaction apparatus is high, and it is easily available.

The concentration of the rare earth element in the active layer is preferably 1×10¹⁷ to 5×10²¹ cm⁻³.

Further, specific examples of p-type dopants include magnesium (Mg), zinc (Zn), and beryllium (Be), but among these, Mg is preferably used. Examples of specific Mg raw materials include organic Mg compounds such as Cp₂Mg (bis(cyclopentadienyl) magnesium).

The concentration of p-type dopant in the p-type doped layer, near the interface with the p-type layer, is preferably 1×10¹⁷ to 1×10²⁰ cm⁻³ from the viewpoint of promoting the movement of holes within the active layer.

Further, from the viewpoint of intentionally controlling the local structure around rare earth element ions in the active layer, it is preferable that the active layer further contains an oxygen element. Note that the content of oxygen element is preferably 1×10¹⁷ to 1×10²⁰ cm⁻³.

### 3. Method for Producing a Rare-Earth-Doped Semiconductor Device According to the Present Invention

Hereinafter, a method for producing a rare-earth-doped semiconductor device according to the present invention will be explained.

The rare-earth-doped semiconductor device according to the present invention described above can be produced by a method in which the formation of the n-type layer, the formation of the active layer, and the formation of the p-type layer are performed using an organometallic vapor phase epitaxy (OMVPE method) under the temperature condition of 900 to 1200° C. in a series without being taken out from the reaction vessel; and, when forming the active layer, a p-type dopant is added together with a rare earth element to the p-type layer side of the active layer to form a p-type doped layer.

in a series under the temperature conditions of 900 to 1200° C. using organometallic vapor phase epitaxy without being taken out the reaction vessel; and, when forming the active layer, a p-type dopant is added together with a rare earth element to the p-type layer side of the active layer to form a p-type doped layer.

At this time, either the n-type layer or the p-type layer may be formed on the substrate first. Specifically, when forming the n-type layer first, after forming the n-type layer on the substrate, a rare earth element is added to the base material to form an active layer to a predetermined thickness, and then a p-type dopant is added together with a rare earth element to the base material to form a p-type doped layer to a predetermined thickness, followed by further forming a p-type layer on the active layer.

On the other hand, when forming the p-type layer first, after forming the p-type layer on a substrate, a p-type dopant is added to the base material together with a rare earth element to form a p-type doped layer to a predetermined thickness. Then, a rare earth element is added to the base material to form an active layer to a predetermined thickness, and further, an n-type layer is formed on the active layer.

In this way, by forming the p-type layer, active layer, and n-type layer in a series of formation steps, that is, by sequentially forming a p-type layer, an active layer, and an n-type layer (or an n-type layer, an active layer, and a p-type layer) in a reaction vessel, without taking them out of the reaction vessel midway, there is no interface state between the layers, and carriers are efficiently injected. As a result, a rare-earth-doped semiconductor device having excellent emission intensity can be produced at low cost with high production efficiency.

The temperature in the reaction vessel is controlled at 900 to 1200° C. in consideration of appropriate ionization of the rare earth element and desorption from the surface of the active layer. More preferably, the temperature is 950 to 1050° C.

Note that in order to efficiently add rare earth elements and p-type dopants to the base material using organometallic vapor phase epitaxy, the atmospheric pressure when forming the active layer is preferably 5 to 60 kPa. Thereby, the active layer (including the p-type doped layer) can be grown in a stable state by appropriately controlling the thermal convection of the source gas in the reaction vessel.

The growth rate when forming the active layer is preferably 0.1 to 4μ m/h, which allows the active layer (including the p-type doped layer) to grow in a stable state. More preferably, the growth rate is 0.1 to 1μ m/h.

### EXAMPLES

Hereinafter, the present invention will be explained in more detail based on Examples. In the example, a rare-earth-doped semiconductor device having the configuration shown in FIG. 1 was produced and evaluated.

### 1. Preparation of Rare-Earth-Doped Semiconductor Devices

First, four types of rare-earth-doped semiconductor devices were produced according to the procedure shown below.

First, a GaN buffer layer (thickness: 30 nm) was grown on a sapphire substrate using the OMVPE method.

Next, similarly, an undoped GaN layer (thickness: 1700 nm) was grown on the GaN buffer layer using the OMVPE method.

Next, an n-type layer 13 (n-GaN: thickness 2500 nm) was formed on the undoped GaN layer.

Next, an active layer 11 (thickness: 300 nm) was formed on the n-type layer 13. At this time, first, an Eu-doped active layer 11b in which only Eu is added to GaN is grown to a predetermined thickness (75 nm, 150 nm, 225 nm, 300 nm), and then a p-type doped layer 11a to which Eu and Mg were added to GaN was grown until the thickness of the active layer 11 becomes 300 nm. At this time, oxygen gas 02 was supplied together with the Eu raw material and the Mg raw material (supply amount: 150 cc/min).

The thicknesses of the Eu-doped active layer 11b and the p-type doped layer 11a described above were controlled by adjusting the growth time of each layer. Specifically, for example, when forming the Eu-doped active layer 11b with a thickness of 225 nm and the p-type doped layer 11a with a thickness of 75 nm, the growth time is 16.5 minutes and 5 minutes, respectively.

Next, a p-type layer 12 (p-GaN: thickness: 120 nm) was formed on the active layer 11.

In the above, trimethyl gallium (TMGa) was used as the Ga raw material, and the supply rate was 5.25 cc/min.

In addition, ammonia was used as the N raw material, and the supply rate was 4 L/min.

Furthermore, as the Eu raw material, EuCp^{pm}₂ bubbled with carrier gas (hydrogen gas: H₂) was used, and the supply rate was 1.5 L/min (supply temperature: 130° C.).

Cp₂Mg was used as the Mg raw material, and the supply rate was 33 cc/min.

The growth temperature of the active layer 11 was set at 960° C.

### 2. Determination of Eu Content and Mg Content

For each sample in which the active layer 11 had been formed, the depth distribution of elements contained in each sample was measured by secondary ion mass spectrometry (SIMS). An example of the results is shown in FIG. 5. Note that FIG. 5 shows the measurement results for a sample in which a p-type doped layer (GaN+Eu+Mg) with a thickness of 75 nm (¼ of the total thickness of the active layer) is formed on an Eu-doped active layer (GaN+Eu) with a thickness of 225 nm. In FIG. 5, the vertical axis is the concentration of each element (atoms/cc), the horizontal axis is the depth (nm) from the p-Gan layer surface (depth up to 800 nm is shown). The horizontal axis also describes corresponding layers from the surface of the Gan layer to the n-GaN layer.

It can be seen from FIG. 5 that the Eu concentration in the Eu-doped active layer 11b is 1.0×10²⁰ cm⁻³ and the Mg concentration in the p-type dopant layer 11a is 3×10¹⁹ cm⁻³.

### 3. Characteristic Evaluation

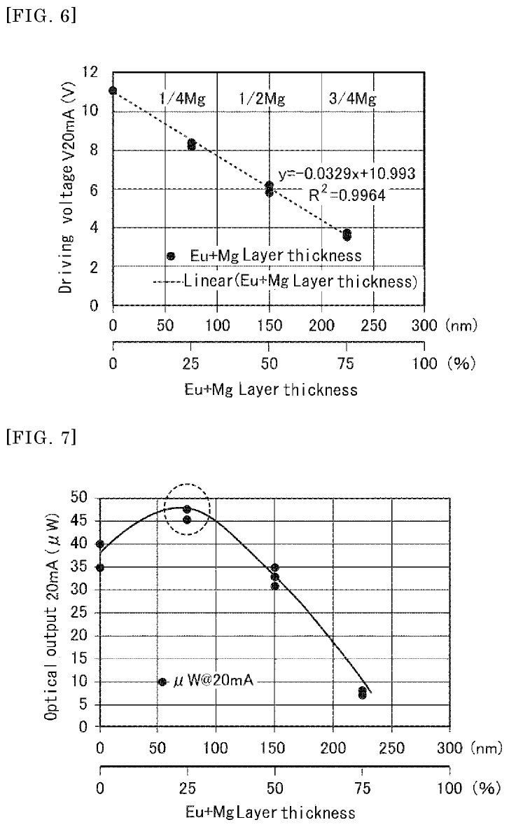

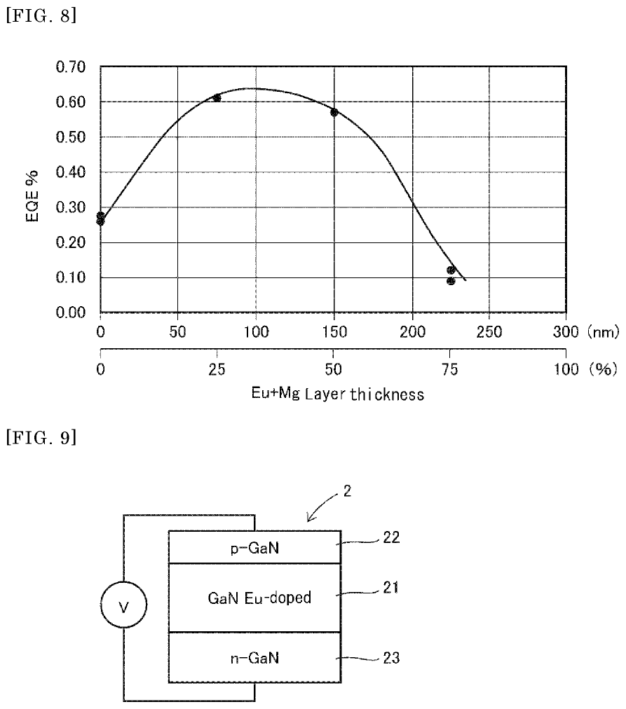

The four types of rare-earth-doped semiconductor devices produced were evaluated in terms of three items: driving voltage V when a current of 20 mA was applied, optical output, and EQE %. The evaluation results are shown in FIG. 6, FIG. 7, and FIG. 8, respectively. In addition, in FIG. 6, FIG. 7, and FIG. 8, the vertical axes are the driving voltage (V), optical output (μW), and EQE %, respectively, and all of the horizontal axes are the layer thickness (nm) of the “Eu+Mg layer” which is a p-type doped layer. The ratios (%) occupied by the “Eu+Mg layer” in the active layer are also listed.

From FIG. 6, it can be seen that the driving voltage (V20 mA) decreases linearly in accordance with the thickness of the p-type doped layer (Eu+Mg layer). Specifically, in FIG. 6, it can be expressed by the approximate expression y=−0.0329x+10.993, and considering that the coefficient of determination (R2) is almost 1, it can be seen that there is a strong correlation between the thickness of the p-type doped layer and the driving voltage.

From FIG. 7, when the thickness of the p-type doped layer (Eu+Mg layer) is 25%, the optical output is maximum (48μ W), and it can be seen that the optical output is improved by more than 1.2 times as compared to the optical output of 39 μW when p-type doped layer is not provided (thickness of the Eu+Mg layer: 0%).

Moreover, from FIG. 8, when the thickness of the p-type doped layer (Eu+Mg layer) is 30%, EQE % becomes maximum (0.64%), and it can be seen that the EQE % is improved by more than 2.3 times as compared to the EQE % (0.27%) when p-type doped layer is not provided (thickness of the Eu+Mg layer: 0%).

Furthermore, when comparing the case where the thickness of the p-type doped layer (Eu+Mg layer) is 25% and the case where it is 50%, the EQE % are 0.61% and 0.58%, which are almost the same (see FIG. 8). However, the driving voltage has decreased by about 30% from 8.2V to 6.0V (see FIG. 6). That is, it can be seen that by setting the thickness of the p-type doped layer (Eu+Mg layer) to 50%, the power efficiency (WPE %: Wall-plug efficiency) increases by 25% compared to a case where the thickness is 25%.

These results show that by providing a p-type doped layer with an appropriate thickness in the p-type layer side of the active layer, the carrier balance can be improved and the emission intensity can be improved, that is, the EQE % can be improved.

In the above description, the active layer is one layer, but the active layer may have a multi-layered structure (MLS structure) in which rare earth-doped thin layers and rare-earth-undoped thin layers are alternately stacked. By providing a p-type doped layer in the rare earth-doped thin layer, further improvements in emission intensity and EQE % can be expected.

Although the present invention has been described above based on the embodiments, the present invention is not limited to the above embodiments. Various modifications can be made to the above embodiments within the same and equivalent scope as the present invention.

### DESCRIPTION OF THE REFERENCE NUMERALS

1, 2 rare-earth-doped semiconductor device
11, 21 active layer
11a p-type doped layer
11b Eu-added active layer
12, 22 p-type layer
13, 23 n-type layer

1. A rare-earth-doped semiconductor device using GaN, InN, AlN, or an alloy compound semiconductor of two or more of these as a base material and a rare earth-doped active layer being provided between an n-type layer and a p-type layer, characterized in that a p-type doped layer in which a p-type dopant is added together with a rare earth element is formed in the p-type layer side of the active layer to have a thickness of ¼ to ½ of the active layer.

2. The rare-earth-doped semiconductor device according to claim 1, characterized in that the concentration of the p-type dopant decreases from the p-type layer side toward an inner layer portion, in the p-type doped layer.

3. The rare-earth-doped semiconductor device according to claim 1, characterized in that the p-type doped layer is formed by stacking a plurality of layers having different concentrations of the p-type dopant so that the concentration of the p-type dopant decreases from the p-type layer side toward the inner layer portion.

4. (canceled)

5. The rare-earth-doped semiconductor device according to claim 1, characterized in that the concentration of the rare earth element in the active layer is 1×10¹⁷ to 5×10²¹ cm⁻³.

6. The rare-earth-doped semiconductor device according claim 1, characterized in that the rare earth element is europium (Eu).

7. The rare-earth-doped semiconductor device according claim 1, characterized in that the concentration of the p-type dopant in the vicinity of the interface between the active layer and the p-type layer is 1×10¹⁷ to 1×10²⁰ cm⁻³.

8. The rare-earth-doped semiconductor device according claim 1, characterized in that the p-type dopant is magnesium (Mg).

9. The rare-earth-doped semiconductor device according claim 1, characterized in that oxygen element is further added to the active layer.

10. The rare-earth-doped semiconductor device according to claim 9, characterized in that the concentration of the oxygen element in the active layer is 1×10¹⁷ to 1×10²⁰ cm⁻³.

11. A method for producing a rare-earth-doped semiconductor device having an active layer formed by using GaN, InN, AlN, or an alloy compound semiconductor of two or more of these as a base material and adding a rare earth element which is formed between an n-type layer and a p-type layer, characterized in that
the formation of the n-type layer, the formation of the active layer, and formation of the p-type layer are performed in a series under the temperature conditions of 900 to 1200° C. using organometallic vapor phase epitaxy without being taken out from the reaction vessel; and, when forming the active layer, a p-type dopant is added together with a rare earth element to the p-type layer side of the active layer to form a p-type doped layer.

12. The method for producing a rare-earth-doped semiconductor device according to claim 11, characterized in that the atmospheric pressure when forming the active layer is 5 to 60 kPa.

13. The method for producing a rare-earth-doped semiconductor device according to claim 11, characterized in that the growth rate when forming the active layer is 0.1 to 4 m/h.

14. The method for producing a rare-earth-doped semiconductor device according to claim 11, characterized in that after forming the n-type layer on a substrate, an active layer of a predetermined thickness is formed by adding a rare earth element to the base material, then a p-type doped layer of a predetermined thickness is formed by adding a p-type dopant together with a rare earth element to the base material, followed by forming the p-type layer.

15. The method for producing a rare-earth-doped semiconductor device according to claim 11, characterized in that after forming the p-type layer on a substrate, a p-type doped layer of a predetermined thickness is formed by adding a p-type dopant together with a rare earth element to the base material, then an active layer of a predetermined thickness is formed by adding a rare earth element to the base material, followed by forming the n-type layer.

16. The method for producing a rare-earth-doped semiconductor device according to claim 11, characterized in that europium (Eu) is used as the rare earth element and magnesium (Mg) is used as the p-type dopant.
